(19) United States
(12) Patent Application Publication
(10) Pub. No.: US 2008/0067000 A1
(43) Pub. Date: Mar. 20, 2008

(54) Environmental noise shielding apparatus

(75) Inventor: Peter Heiland, Raunheim (DE)

Correspondence Address: DEMONT & BREYER, LLC, 100 COMMONS WAY, Ste. 250, HOLMDEL, NJ, 07733, US

(73) Assignee: INTEGRATED DYNAMICS ENGINEERING GMBH, Raunheim (DE)

(21) Appl. No.: 11/855,057

(22) Filed: Sep. 13, 2007

(30) Foreign Application Priority Data
Sep. 19, 2006 (EP) 06 019 536
Oct. 30, 2006 (EP) 06 022 659

(51) Int. Cl. E04B 1/84; H05K 7/20

(52) U.S. Cl. 181/284; 361/688

(57) ABSTRACT

The invention relates to an environmental noise shielding apparatus in which the internal temperature can be matched to the external temperature by means of a cooling element which is arranged within the environmental noise shielding apparatus. This allows a better sound protection effect.

### FIELD OF THE INVENTION

The invention relates to an environmental noise shielding apparatus, and to a method for shielding an appliance against environmental noise.

### BACKGROUND TO THE INVENTION

Apparatuses for an acoustic shielding of sensitive appliances are known from practical use. So-called acoustic shrouds are used to shield sensitive inspection machines, particularly in the semiconductor industry.

A housing which provides sound attenuation such as this at the same time generally also provides heat isolation. Particularly when an appliance is incorporated in a housing which produces heat losses, significant temperature increases can therefore occur in the interior of the housing. In many cases, a temperature increase such as this is undesirable. Particularly when using a housing to isolate inspection appliances in the semiconductor industry, it is desirable for the interior of the sound protection shroud to be essentially at the same temperature as the external area in order, for example, to ensure that wafers which are introduced into the interior are not subject to temperature fluctuations. In practice, attempts have been made to reduce the heating of such sound protection shrouds by fans.

Fans such as these have the disadvantage that, even if they are fitted in a manner which in particular attenuates sound, an aperture opening is still also created for sound, thus reducing the sound isolation effect of the housing.

### OBJECT OF THE INVENTION

In contrast, the invention is based on the object of providing an apparatus for protection of a sensitive appliance against environmental noise, in which the disadvantages mentioned with the prior art are reduced.

One particular object of the invention is to provide an apparatus which improves the sound protection effect.

A further object of the invention is to provide a sound protection apparatus in which the internal temperature can be kept at the same level as the external temperature.

### SUMMARY OF THE INVENTION

The object of the invention is achieved just by an environmental noise shielding apparatus and by a method for shielding an appliance against environmental sound, as claimed in one of the independent claims.

Preferred embodiments and developments of the invention can be found in the respective dependent claims.

According to the invention, an environmental noise shielding apparatus is provided which has a housing which defines an area for holding an isolating appliance.

The expression an environmental noise shielding apparatus means an apparatus in which an appliance to be isolated can be arranged, and in which the noise volume is reduced by the housing of the apparatus, that is to say the sound level in the area for holding an appliance to be isolated is lower than in the surrounding area.

According to the invention, at least one cooling element is arranged in that area. A cooling element is any apparatus by means of which the area for holding the appliance to be isolated can be cooled.

In one preferred embodiment of the invention, the cooling element is coupled to at least one supply device, which is arranged outside the appliance. The supply device is preferably essentially decoupled from the housing, that is to say vibration of the supply device is not transmitted to the housing of the appliance to be isolated.

By way of example, compressor cooling elements, Peltier elements or cooling meander circuits can be used for cooling purposes, which are fitted to one or more points on the inner wall of the housing, or may be parts of the walls or of the lids.

The choice of the cooling element is in this case governed primarily by the requirements for the cooling power. Since the heat losses, particularly from inspection appliances in the semiconductor industry, are often quite low, Peltier elements or cooling meander circuits in which the heat is dissipated via a fluid, in particular water, are sufficient for many applications. A coolant compressor can also be used for applications in which the cooling power is greater.

Flexible lines, such as those provided for one particular embodiment of the invention, in this case ensure that vibration of the supply device, in particular vibration of a cooling compressor, is not passed on, or is passed on only to a minor extent, to the housing of the environmental noise shielding apparatus.

The cooling element in the housing of the environmental noise shielding apparatus is preferably designed such that it produces a sound level of less than 30 dB, preferably of less than 20 dB, and particularly preferably of less than 15 dB. Cooling elements are therefore used which produce little noise in the interior of the housing.

The cooling element or elements is or are preferably integrated in the wall or lid of the housing, in particular with provision being made for a cooling element to be accommodated essentially in the lid of the housing.

In one development of the invention, a temperature sensor is arranged in the area, and is designed to regulate a supply device for coolant. The temperature in the interior of the housing can be kept constant by using a temperature sensor such as this.

In one alternative embodiment, as is provided according to one development of the invention, a further temperature sensor is arranged outside the area, and can be used to measure the temperature outside the housing. The temperature in the area in the housing can thus be matched to the external temperature. Temperature fluctuations when closing sensitive appliances or components to be investigated in the environmental noise shielding apparatus are largely avoided.

In one development of the invention, the environmental noise shielding apparatus has at least one opening flap which, as provided in one preferred embodiment of the invention, can be operated automatically. For example, the environmental noise shielding apparatus can be integrated in an automatic transport system, in which, for example, samples to be investigated are moved by an automation device into the housing of the environmental noise shielding apparatus.

The area in the environmental noise shielding apparatus can preferably be closed in an essentially fluidtight manner. This increases the sound-isolating effect, and more accurate temperature regulation is possible.

The area preferably occupies a space of between 0.2 and 7 m³, and particularly preferably between 0.5 and 1.5 m³.

The invention makes it possible to provide environmental noise shielding apparatuses which have a sound attenuation at a frequency of 500 Hz and with an incidence angle which runs essentially at right angles to a housing wall of more than 5 dB, preferably of more than 10 dB, and particularly preferably of more than 40 dB.

The sound attenuation at a frequency of 250 Hz is more than 3 dB, preferably more than 8 dB, and particularly preferably more than 30 dB.

The sound attenuation at a frequency of 100 Hz is more than 15 dB, preferably more than 30 dB, and particularly preferably more than 50 dB.

The invention also relates to a vibration isolation system which has an environmental noise shielding apparatus according to the invention.

The environmental noise shielding apparatus is in this case preferably mounted in a vibration-isolated form, in particular with provision being made for the environmental noise shielding apparatus to be arranged on a vibration-isolated plate.

The invention also relates to a method for shielding an appliance against environmental sound, with an appliance to be shielded being introduced into a housing which is then closed, and with a cooling apparatus which is arranged in the housing being regulated by a sensor which is likewise arranged in the housing.

In one development of the invention, the temperature in the housing is matched to the temperature outside the housing by means of a further sensor which is arranged outside the housing.

### BRIEF DESCRIPTION OF THE DRAWINGS

The invention will be explained in more detail in the following text using the drawings, FIG. 1 to FIG. 6, in which:

FIG. 1 shows, schematically, the major components of an environmental noise shielding apparatus,

FIG. 2 shows, schematically, an alternative embodiment of an environmental noise shielding apparatus,

FIG. 3 shows a schematic view of a further alternative embodiment of an environmental noise shielding apparatus,

FIG. 4 shows a schematic illustration, with reference to which the housing of an environmental noise shielding apparatus will be explained,

FIG. 5 shows a further view of an environmental noise shielding apparatus according to the invention, and

FIG. 6 shows a detailed illustration of the area A in FIG. 5.

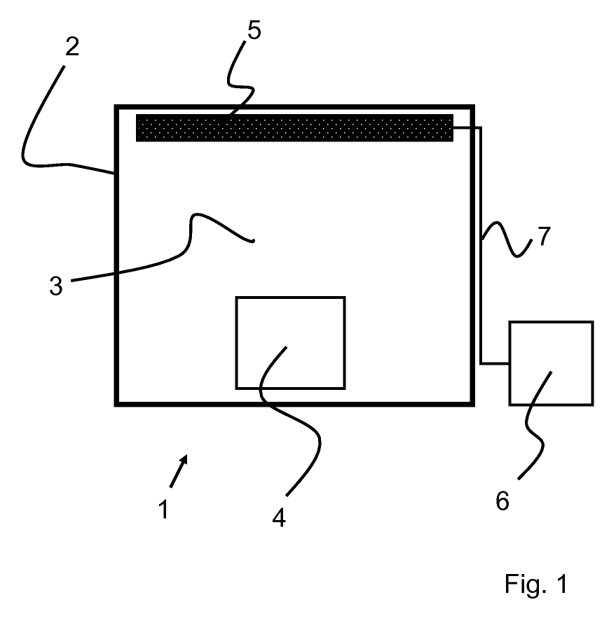

The major components of an environmental noise shielding apparatus 1 will be explained in more detail with reference to FIG. 1. The environmental noise shielding apparatus 1 has a housing 2 to be isolated, which defines an area 3 for holding an appliance 4 to be isolated. A cooling element 5 is arranged in the area 3 of the environmental noise shielding apparatus 1 and is connected via a flexible supply line 7 to a supply device 6, in this case in the form of a coolant compressor. The cooling element 5 is cooled via the supply device 6, thus cooling the area 3 within which the appliance to be isolated is arranged.

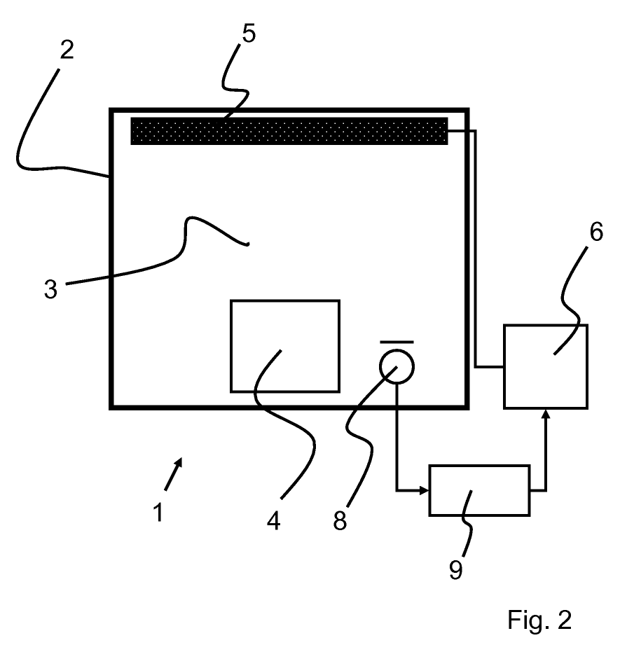

FIG. 2 shows an alternative embodiment of an environmental noise shielding apparatus 1, in which a temperature sensor 8 is arranged in the housing 2. The temperature sensor 8 is located in the vicinity of the appliance 4 to be isolated.

The temperature sensor 8 is connected to a control device 9 which drives the supply device 6. The temperature in the area 3 can be kept essentially constant by means of the control device 9.

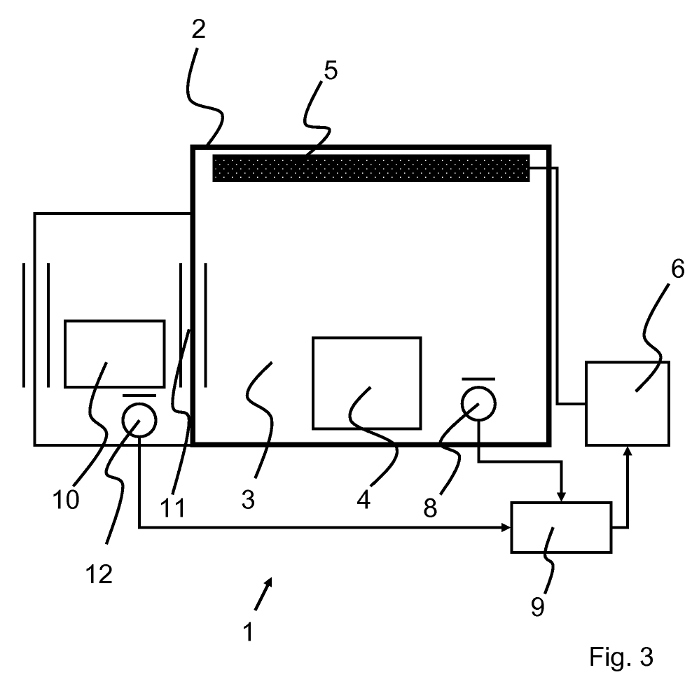

A further embodiment of an environmental noise shielding apparatus will be explained in more detail with reference to FIG. 3. In this embodiment, the housing 2 of the environmental noise shielding apparatus 1 is coupled to a sample transport apparatus 10. The sample transport apparatus 1 can be used to introduce samples (not illustrated) into the area 3 in the environmental noise shielding apparatus 1 via an automatic door 11, and feed said samples to the appliance 4 to be isolated.

A sensor 8 is arranged in the area 3 in the environmental noise shielding apparatus 1, and is connected to a control device 9.

A further sensor 12 is arranged outside the housing 2. The external temperature is measured using this sensor 12.

The control device 9 drives the supply device which is connected to the cooling element 5. The control device 9 is in this case designed such that it matches the temperature in the area 3 in the environmental noise shielding apparatus 1 to the external temperature, which is measured by the sensor 12.

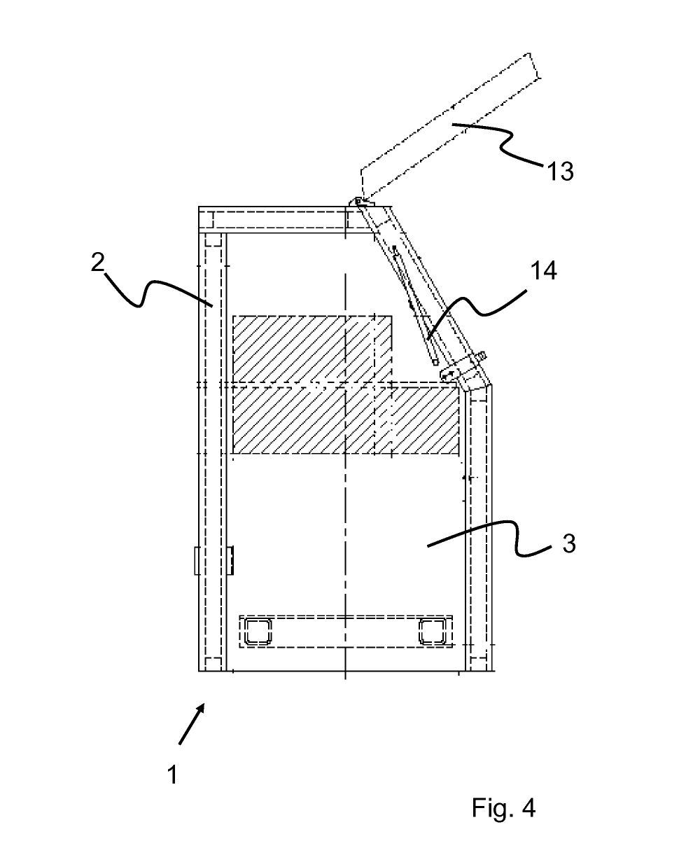

The major components of a housing 2 of a further embodiment of an environmental noise shielding apparatus 1 will be explained in more detail with reference to FIG. 4. The housing 2 has a flap 13, which is held against the housing 2 via gas springs 14. The area 3 in the housing 2 can be closed to be essentially airtight, by means of the flap 13.

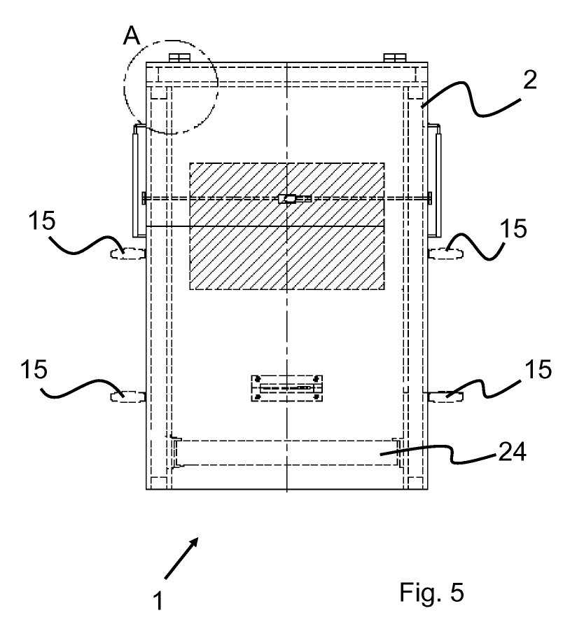

FIG. 5 shows a further view of the housing 2 of the environmental noise shielding apparatus 1. Removable handles 15 are fitted to the housing 2, and can be used to carry the environmental noise shielding apparatus.

Furthermore, the environmental noise shielding apparatus 1 has a receptacle 24 for lifting it, for example by means of a fork lift truck. The receptacle 24 is also designed to be removable.

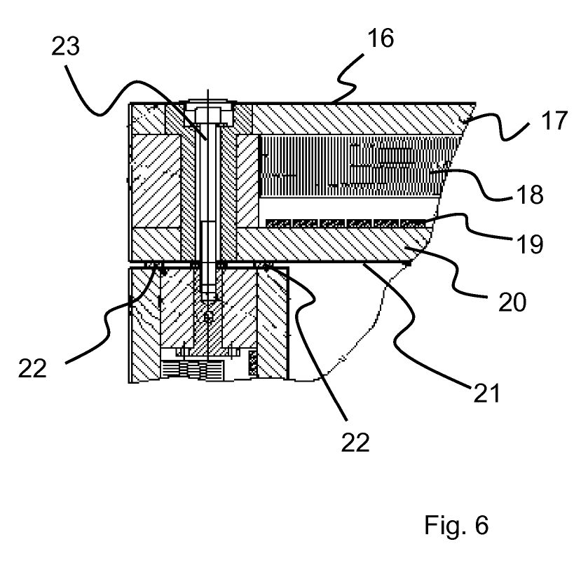

FIG. 6 shows a detailed illustration of the area A in FIG. 5. The design of the housing will be explained in more detail with reference to the detailed illustration. The housing walls are formed from multiple layers of a composite material. In this exemplary embodiment, the walls have an outer laminate film 16, which is adhesively bonded to a piece of chipboard 17. Insulation in the form of mineral wool 18 is located behind the chipboard. A sound attenuating mat 19 is adhesively bonded to a further piece of chipboard 20 in the adjacent cavity. The sound attenuating mat 19 is filled with scrap steel. A film 21 is likewise adhesively bonded to the further piece of chipboard 20. The wall elements are connected to one another by means of screws 23. Seals 22, in this case in the form of silicone seals, are located between the individual wall elements, for noise shielding and to ensure that the housing is fluidtight.

It is self-evident that the invention is not restricted to a combination of the features described above and, instead, a person skilled in the art can combine all of the described features, where worthwhile.

1. An environmental noise shielding apparatus comprising:
a housing which defines an area for holding an appliance to be isolated and
at least one cooling element arranged in the area.

2. The environmental noise shielding apparatus as claimed in claim 1, wherein a supply apparatus is provided for the at least one cooling element, with the supply device being arranged outside the housing.

3. The environmental noise shielding apparatus as claimed in claim 2, wherein the supply device is connected to the at least one cooling element by means of flexible lines and/or cables.

4. The environmental noise shielding apparatus as claimed in claim 1, wherein the cooling element produces a sound level of less than 30 dB in the housing.

5. The environmental noise shielding apparatus as claimed in claim 1, wherein at least one cooling element is integrated in a wall and/or a lid of the housing.

6. The environmental noise shielding apparatus as claimed in claim 1, wherein at least one temperature sensor, which is designed to regulate a supply device for the cooling element, is arranged in the area.

7. The environmental noise shielding apparatus as claimed in claim 1, wherein at least one temperature sensor is arranged outside the area.

8. The environmental noise shielding apparatus as claimed in claim 1, wherein the environmental noise shielding apparatus has at least one opening flap.

9. The environmental noise shielding apparatus as claimed in claim 8, wherein the opening flap can be operated automatically.

10. The environmental noise shielding apparatus as claimed in claim 1, wherein the area can be closed to be essentially fluidtight.

11. The environmental noise shielding apparatus as claimed in claim 1, wherein the area has a size of between 0.2 and 7 m³.

12. The environmental noise shielding apparatus as claimed in claim 1, wherein the sound attenuation from the outside inward with an incidence angle running essentially at right angles to a wall of the housing and of a frequency of 500 Hz is more than 5 dB.

13. A vibration isolation system, comprising at least one environmental noise shielding apparatus as claimed in claim 1.

14. The vibration isolation system as claimed in claim 13, having a plate which is mounted to provide vibration isolation, with the environmental noise shielding apparatus being arranged on the plate.

15. A method for shielding an appliance against environmental sound comprising:
introducing the appliance to be shielded into a housing;
closing the housing; and
regulating a cooling apparatus which is arranged in the housing by a sensor which is arranged in the housing.

16. The method for shielding an appliance against environmental sound as claimed in claim 15, further comprising measuring both the temperature in the housing and the temperature outside the housing wherein the temperature in the housing is essentially matched to the temperature outside the housing by the regulating of the cooling apparatus.
